(19) United States
(12) Patent Application Publication
(10) Pub. No.: US 2023/0040184 A1
(43) Pub. Date: Feb. 9, 2023

(54) A SYSTEM AND A METHOD FOR ESTIMATING ELECTRICAL PROPERTIES OF AN ELECTROLYZER

(71) Applicant: Lappeenrannan-Lahden teknillinen yliopisto LUT, Lappeenranta (FI)

(72) Inventors: Joonas KOPONEN, Lappeenranta (FI); Vesa RUUSKANEN, Lappeenranta (FI); Antti KOSONEN, Lappeenranta (FI); Anton POLUEKTOV, Lappeenranta (FI); Jero AHOLA, Lappeenranta (FI); Markku NIEMELÄ, Lappeenranta (FI); Tuomo LINDH, Lappeenranta (FI)

(21) Appl. No.: 17/791,390

(22) PCT Filed: Jan. 4, 2021
(86) PCT No.: PCT/FI2021/050002

§ 371 Date: Jul. 7, 2022

(30) Foreign Application Priority Data
Jan. 9, 2020 (FI) 20205017

(51) Int. Cl. C25B 15/023; G01R 27/08; C25B 9/65; C25B 1/04; C25B 9/19; H02M 7/219; H02M 7/23

(52) U.S. Cl. CPC C25B 15/023; G01R 27/08; C25B 9/65; C25B 1/04; C25B 9/19; H02M 7/219; H02M 7/23

(57) ABSTRACT

An apparatus for estimating electrical properties of an electrolyzer includes a data processing system for estimating electrical values, for example a membrane resistance, of the electrolyzer based on a difference voltage, a current, and an initial value and an attenuation time constant of a double-layer capacitance voltage of the electrolyzer during a shutdown of the electrolyzer. The difference voltage is a difference between a voltage of the electrolyzer and a total reversible voltage of the electrolyzer. The initial value and the attenuation time constant of the double-layer capacitance voltage are estimated based on values of the difference voltage when the current is zero and thus the difference voltage equals the double-layer capacitance voltage. The electrical values can be estimated even if a stepwise interruption of the current of the electrolyzer is not possible.

### FIELD OF THE DISCLOSURE

The disclosure relates to an apparatus and to a method for estimating electrical properties of an electrolyzer. Furthermore, the disclosure relates to a computer program for estimating electrical properties of an electrolyzer. Furthermore, the disclosure relates to an electrolysis system.

### BACKGROUND

An electrochemical process where material interacts with electrodes can be for example an electrolysis process such as e.g. water electrolysis where electrical energy is converted into chemical energy carried by hydrogen gas, and oxygen gas is produced as a side-product. Direct current is passed between two electrodes, and hydrogen gas is produced at the cathode i.e. the negative electrode, and oxygen gas is produced at the anode i.e. the positive electrode. The Faraday's law of electrolysis states that the production of hydrogen gas is directly proportional to the electric charge transferred at the electrodes. Thus, the mean value of the direct current determines the production rate of hydrogen gas.

In many cases, there is a need to estimate electrical properties of an electrolyzer. The electrical properties may comprise for example an ohmic resistance i.e. a membrane resistance, a charge-transfer resistance, and a double-layer capacitance of electrolytic cells of an electrolyzer. For example, reversible degradation in electrolytic cells is related to an increase in the above-mentioned membrane resistance, which makes online estimation of the membrane resistance especially appealing. More information can be found e.g. in the publication of I. Dedigama, P. Angeli, K. Ayers, J. Robinson, P. Shearing, D. Tsaoulidis, and D. Brett: In situ diagnostic techniques for characterisation of polymer electrolyte membrane water electrolysers flow visualisation and electrochemical impedance spectroscopy, Int. J. Hydrogen Energy 39, 9, 2014, pp. 4468-4482. The estimated electrical properties of an electrolyzer can be used for controlling the operation of the electrolyzer to improve the efficiency and/or to lengthen the lifetime of the electrolyzer.

There are many known methods for estimating electrical properties of an electrolyzer, for example: polarization curve identification, electrochemical impedance spectroscopy “EIS”, current mapping “CM”, and current interrupt “CI”. The polarization curve identification gives a current-voltage behaviour of an electrolytic cell or a cell stack, and it can be used to assess the overall performance of an electrolyzer. Collection of polarization curve data requires testing the steady-state operation throughout the range of operating conditions, i.e. with different current densities, and may therefore be time consuming and cumbersome to carry out in conjunction with an industrial electrolyzer.

In the electrochemical impedance spectroscopy “EIS”, an electrolytic cell is supplied with a direct current with an alternating current component superimposed. This method may give a detailed, small-signal level information on an electrolytic cell performance but requires that a suitable alternating component can be added to the direct current, and that the current and voltage can be measured with a high precision at a high sampling frequency. Therefore, the application of the electrochemical impedance spectroscopy for industrial, megawatt-scale electrolyzers faces significant challenges compared to a single cell identification with the electrochemical impedance spectroscopy.

In the current mapping “CM” method, local current density distributions are analysed. Some current mapping methods require physical modifications to an electrolytic cell structure to enable measurement of a current distribution among an electrolytic cell area. A known non-invasive current mapping method has been presented by K.-H. Hauer, R. Potthast, T. Wüster: Magnetotomography—a new method for analysing formance and quality, J. Power Sources 143, 1, 2005, pp. 67-74. This non-invasive current mapping method is based on a three-dimensional measurement of a magnetic flux caused by a current flow in an electrolytic cell. The non-invasive current mapping method requires additional equipment, and its accuracy may be insufficient for industrial electrolyzers.

The current interrupt “CI” method comprises two parts: 1) a natural voltage response, where steady-state operation of an electrolyzer is abruptly stopped and a voltage response is recorded, and 2) a current switching technique. In the first part, the membrane resistance is estimated, and then in the second part, the charge transfer resistance, and the double-layer capacitance are identified. In some cases, also the Warburg impedance that plays a role at high current densities is identified. More information can be found e.g. in the publication of J. van der Merwe, K. Uren, G. van Schoor, D. Bessarabov: Characterisation tools development for PEM electrolysers, Int. J. Hydrogen Energy 39, 26, 2014 pp. 14212-14221. Especially in industrial, megawatt-scale electrolyzers, the drop rate of a current is limited by a safe slew rate of a rectifier and by a di/dt limitation due to an inductance of a rectifier output filter. As a stepwise current interruption is not possible in conjunction with industrial electrolyzers, the electrical properties cannot be estimated with the traditional current interrupt “CI” method.

### SUMMARY

The following presents a simplified summary in order to provide a basic understanding of some aspects of various embodiments. The summary is not an extensive overview of the invention. It is neither intended to identify key or critical elements of the invention nor to delineate the scope of the invention. The following summary merely presents some concepts in a simplified form as a prelude to a more detailed description of exemplifying and non-limiting embodiments.

In accordance with the invention, there is provided a new apparatus for estimating electrical properties of an electrolyzer. An apparatus according to the invention comprises current and voltage sensors for measuring a voltage applied on the electrolyzer and a current of the electrolyzer. Furthermore, the apparatus comprises a data processing system for:
storing data indicative of a value u₀ of a difference voltage prevailing at a beginning of a shutdown of the electrolyzer and a value I₀ of the current of the electrolyzer prevailing at the beginning of the shutdown, the difference voltage being a difference between the voltage applied on the electrolyzer and a total reversible voltage of the electrolyzer,
in response to a situation in which the current has reached zero, computing an estimate τ for a time constant of exponential attenuation of a double-layer capacitance voltage of the electrolyzer and an estimate u_{0C} for the double-layer capacitance voltage prevailing at the beginning of the shutdown based on two or more values of the difference voltage when the current is zero and thus the difference voltage equals the double-layer capacitance voltage, and
computing at least one of the following: i) an estimate for a membrane resistance Rₘ of the electrolyzer as Rₘ=(u₀−u_{0C})/I₀, ii) an estimate for a charge-transfer resistance R_{ct} of the electrolyzer as R_{ct}=u_{0C}/I₀, and iii) an estimate for a double-layer capacitance C_{dl} of the electrolyzer as C_{dl}=τ I₀/u_{0C}.

The membrane resistance Rₘ and/or the charge-transfer resistance R_{ct} and/or the double-layer capacitance C_{dl} can be estimated even if a stepwise interruption of the current of the electrolyzer is not possible. A stepwise current interruption is difficult or even impossible especially in conjunction with industrial electrolyzers where a drop rate of a current is limited by a safe slew rate of a rectifier and by a di/dt limitation due to an inductance of a rectifier output filter.

In accordance with the invention, there is provided also a new electrolysis system that comprises:
an electrolyzer,
a rectifier circuitry for receiving one or more alternating voltages and for supplying a direct current to electrodes of the electrolyzer,
a controller for controlling the direct current supplied to the electrodes of the electrolyzer, and
an apparatus according to the invention for estimating electrical properties of the electrolyzer.

The electrolyzer can be, for example but not necessarily, an alkaline water electrolyzer where electrodes operate in alkaline liquid electrolyte that may comprise e.g. aqueous potassium hydroxide “KOH” or aqueous sodium hydroxide “NaOH”.

In accordance with the invention, there is provided also a new method for estimating electrical properties of an electrolyzer. A method according to the invention comprises:
storing data indicative of a value u₀ of a difference voltage prevailing at a beginning of a shutdown of the electrolyzer and a value I₀ of a current of the electrolyzer prevailing at the beginning of the shutdown, the difference voltage being a difference between a voltage applied on the electrolyzer and a total reversible voltage of the electrolyzer,
in response to a situation in which the current has reached zero, computing an estimate τ for a time constant of exponential attenuation of a double-layer capacitance voltage of the electrolyzer and an estimate u_{0C} for the double-layer capacitance voltage prevailing at the beginning of the shutdown based on two or more values of the difference voltage when the current is zero and thus the difference voltage equals the double-layer capacitance voltage, and
computing at least one of the following: i) an estimate for a membrane resistance Rₘ of the electrolyzer as Rₘ=(u₀−u_{0C})/I₀, ii) an estimate for a charge-transfer resistance R_{ct} of the electrolyzer as R_{ct}=u_{0C}/I₀, and iii) an estimate for a double-layer capacitance C_{dl} of the electrolyzer as C_{dl}=τ I₀/u_{0C}.

In cases where an electrolysis system comprises means for e.g. the electrochemical impedance spectroscopy “EIS” and/or for another estimation method, the method according to the invention can be used in combination with the electrochemical impedance spectroscopy and/or the other estimation method.

In accordance with the invention, there is provided also a new computer program for estimating electrical properties of an electrolyzer. A computer program according to the invention comprises computer executable instructions for controlling a programmable processor to:
receive, from voltage and current sensors, data indicative of a voltage applied on the electrolyzer and a current of the electrolyzer,
store data indicative of a value u₀ of a difference voltage prevailing at a beginning of a shutdown of the electrolyzer and a value I₀ of the current of the electrolyzer prevailing at the beginning of the shutdown, the difference voltage being a difference between the voltage applied on the electrolyzer and a total reversible voltage of the electrolyzer,
in response to a situation in which the current has reached zero, compute an estimate τ for a time constant of exponential attenuation of a double-layer capacitance voltage of the electrolyzer and an estimate u_{0C} for the double-layer capacitance voltage prevailing at the beginning of the shutdown based on two or more values of the difference voltage when the current is zero and thus the difference voltage equals the double-layer capacitance voltage, and
compute at least one of the following: i) an estimate for a membrane resistance Rₘ of the electrolyzer as Rₘ=(u₀−u_{0C})/I₀, ii) an estimate for a charge-transfer resistance R_{ct} of the electrolyzer as R_{ct}=u_{0C}/I₀, and iii) an estimate for a double-layer capacitance C_{dl} of the electrolyzer as C_{dl}=τ I₀/u_{0C}.

In accordance with the invention, there is provided also a new computer program product. The computer program product comprises a non-volatile computer readable medium, e.g. a compact disc “CD”, encoded with a computer program according to the invention.

Exemplifying and non-limiting embodiments are described in accompanied dependent claims.

Various exemplifying and non-limiting embodiments both as to constructions and to methods of operation, together with additional objects and advantages thereof, will be best understood from the following description of specific exemplifying and non-limiting embodiments when read in conjunction with the accompanying drawings.

The verbs “to comprise” and “to include” are used in this document as open limitations that neither exclude nor require the existence of unrecited features. The features recited in dependent claims are mutually freely combinable unless otherwise explicitly stated. Furthermore, it is to be understood that the use of “a” or “an”, i.e. a singular form, throughout this document does not exclude a plurality.

### BRIEF DESCRIPTION OF THE FIGURES

Exemplifying and non-limiting embodiments and their advantages are explained in greater detail below in the sense of examples and with reference to the accompanying drawings, in which:

FIG. 1a illustrates an electrolysis system that comprises an apparatus according to an exemplifying and non-limiting embodiment for estimating electrical properties of an electrolyzer of the electrolysis system,

FIG. 1b shows an equivalent circuit of an electrolytic cell,

FIG. 1c shows exemplifying time trends of a voltage and a current of an electrolyzer during shutdown of the electrolyzer, and

FIG. 2 shows a flowchart of a method according to an exemplifying and non-limiting embodiment for estimating electrical properties of an electrolyzer.

### DESCRIPTION OF THE EXEMPLIFYING EMBODIMENTS

The specific examples provided in the description given below should not be construed as limiting the scope and/or the applicability of the appended claims. Lists and groups of examples provided in the description given below are not exhaustive unless otherwise explicitly stated.

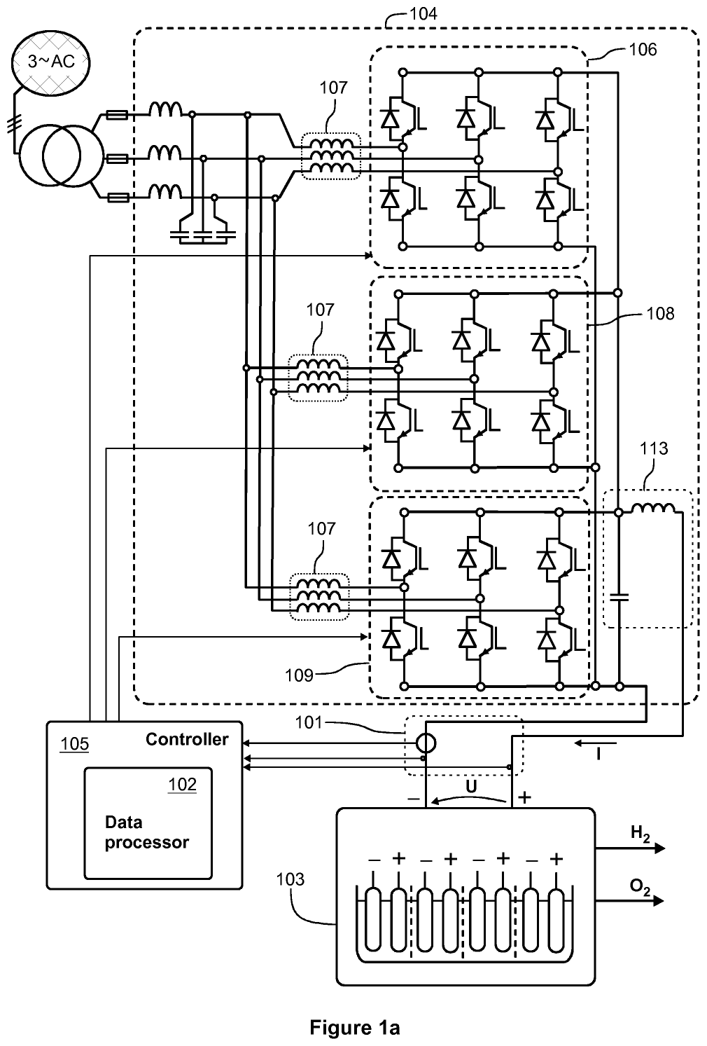

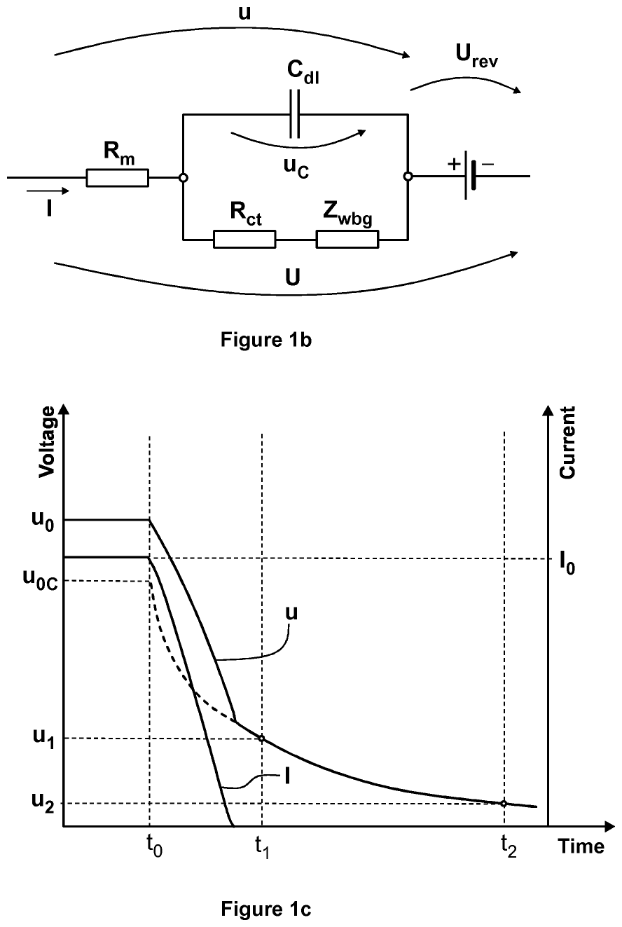

FIG. 1a illustrates an electrolysis system according to an exemplifying and non-limiting embodiment. The electrolysis system comprises an electrolyzer 103 that comprises one or more electrolysis cells each of which contains an anode, a cathode, and electrolyte. In this exemplifying case, the electrolyzer 103 is a water electrolyzer where electrical energy is converted into chemical energy carried by hydrogen gas H₂. Oxygen gas O₂ is produced as a side-product. The electrolyzer 103 can be, for example but not necessarily, an alkaline water electrolyzer where each electrolytic cell contains alkaline liquid electrolyte and a porous diaphragm dividing the electrolysis cell into a cathode compartment containing a cathode and an anode compartment containing an anode. The alkaline liquid electrolyte that may comprise e.g. aqueous potassium hydroxide “KOH” or aqueous sodium hydroxide “NaOH”. The electrolyzer 103 may comprise e.g. tens or even hundreds of electrolysis cells. It is however also possible that the electrolyzer 103 comprises from one to ten electrolysis cells. The electrolysis cells can be electrically series connected or electrically parallel connected. It is however also possible that the electrolytic cells are arranged to constitute series connected groups of parallel connected electrolytic cells, or parallel connected groups of series connected electrolytic cells, or the electrolytic cells are electrically connected to each other in some other way.

The electrolysis system comprises a rectifier circuitry 104 for receiving alternating voltages and for supplying a direct current I to the electrodes of the electrolyzer 103. In this exemplifying case, the rectifier circuitry 104 comprises forced-commutated converter bridges 106, 108, and 109 and supply inductors 107 at alternating voltage sides of the forced-commutated converter bridges. Furthermore, the rectifier circuitry 104 comprises a direct current filter 113 for smoothing the current I of the electrolyzer 103. The forced-commutated converter bridges 106, 108, and 109 are connected to each other so that the current supplied to the direct current filter 113 is a sum of direct currents produced by the forced-commutated converter bridges. Each of the forced-commutated converter bridges 106, 108, and 109 comprises converter legs each comprising an alternating voltage terminal and being connected between direct voltage terminals of the converter bridge under consideration. Each converter leg comprises a bi-directional upper-branch controllable switch between the alternating voltage terminal of the converter leg under consideration and a positive one of the direct voltage terminals and a bi-directional lower-branch controllable switch between the alternating voltage terminal of the converter leg under consideration and a negative one of the direct voltage terminals. In the exemplifying case illustrated in FIG. 1a, each bi-directional controllable switch comprises an insulated gate bipolar transistor “IGBT” and an antiparallel diode. It is however also possible that each bi-directional controllable switch comprises e.g. a gate turn-off thyristor “GTO”, or a metal oxide field effect transistor “MOSFET”, or some other suitable semiconductor switch in lieu of the IGBT.

The electrolysis system comprises a controller 105 for controlling the operation of the controllable switches so that desired current is supplied to the electrolyzer 103 and desired alternating voltages occur at the alternating voltage terminals of the forced-commutated converter bridges 106, 108, and 109. Forced commutation of the bi-directional switches of the converter bridges 106, 108, and 109 enables reduction of current ripple in the current I supplied to the electrolyzer 103. Furthermore, the forced commutation of the bi-directional switches enables to control the power factor of an alternating voltage supply of the electrolysis system and current harmonics injected to the alternating voltage supply.

FIG. 1b shows an equivalent circuit of an electrolytic cell of the electrolyzer 103. The impedance of the electrolytic cell consists of the membrane resistance Rₘ, the charge-transfer resistance Ret, and the double-layer capacitance C_{dl}. To account for mass transfer losses, the Warburg impedance Z_{wbg} is to be included in the equivalent circuit. However, the Z_{wbg} is relevant only at high current densities and low frequencies. In further considerations, the Warburg impedance Z_{wbg} is assumed to be zero. Uᵣₑᵥ is the reversible voltage of the electrolytic cell. The reversible voltage Uᵣₑᵥ is the minimum cell voltage for the electrochemical reaction to occur. The reversible voltage Uᵣₑᵥ can be estimated based on the electrolyzer operating temperature and pressure. For example, an estimate for the reversible voltage of an alkaline water electrolysis is given by the following formula:

Uᵣₑᵥ=ΔG₀/(2F)−ln(P/P₀)RT/(2F),

where ΔG₀ is an increment of Gibbs free energy, F is the Faraday constant, R is the gas constant, T is the absolute temperature, and P₀ and P are vapor pressures of pure water and the electrolyte, respectively. The ΔG₀/(2F) is 1.226 Volts under 298 K and 1 atm.

The equivalent circuit shown in FIG. 1b can be used for a series connection of electrolytic cells so that the membrane resistance Rₘ is deemed to correspond to the membrane resistance of the series connected electrolytic cells, the charge-transfer resistance R_{ct} is deemed to correspond to the charge-transfer resistance of the series connected electrolytic cells, the double-layer capacitance C_{dl} is deemed to correspond to the double-layer capacitance of the series connected electrolytic cells, Uᵣₑᵥ is deemed to correspond to the total reversible voltage of the series connected electrolytic cells, and U is the voltage of the series connected electrolytic cells. Correspondingly, the equivalent circuit shown in FIG. 1b can be used for a parallel connection of electrolytic cells.

FIG. 1c shows exemplifying time trends of a difference voltage u and the current I of the electrolyzer 103 during a shutdown of the electrolyzer. The difference voltage u is the difference between the voltage U applied on the electrolyzer and the total reversible voltage of the electrolyzer, i.e. u=U−Uᵣₑᵥ.

The electrolysis system shown in FIG. 1a comprises an apparatus according to an exemplifying and non-limiting embodiment for estimating electrical properties of the electrolyzer 103. The apparatus comprises current and voltage sensors 101 for measuring the voltage U applied on the electrolyzer 103 and the current I of the electrolyzer 103. Furthermore, the apparatus comprises a data processing system 102 that is configured to store, into a memory circuit, data indicative of a value u₀ of the difference voltage prevailing prior to and at a beginning of a shutdown of the electrolyzer 103 and a value I₀ of the current I of the electrolyzer prevailing prior to and at the beginning of the shutdown. In the exemplifying case shown in FIG. 1c, the shutdown begins at a time instant t₀. The data processing system 102 is configured to compute an estimate τ for a time constant of exponential attenuation of a double-layer capacitance voltage u_{C} of the electrolyzer and an estimate u_{0C} for the double-layer capacitance voltage prevailing at the beginning of the shutdown based on two or more values of the difference voltage u when the current I is zero and thus the difference voltage u equals the double-layer capacitance voltage u_{C}.

The above-mentioned difference voltage u can be estimated with the following formula when the current I is zero:

u=u_{0C}e^{-(t-t0)/τ},

where u_{0C} is an estimate for the double-layer capacitance voltage of the electrolyzer prevailing at the beginning of the shutdown, and e is the Napier's constant≈2.71828. The double-layer capacitance voltage u_{C} can be estimated as u_{0C}e^{-(t-t0)/τ} on and after the beginning of the shutdown of the electrolyzer, i.e. when time to.

FIG. 1c shows exemplifying values u₁ and u₂ of the difference voltage u corresponding to time instants t₁ and t₂ at which the current I is zero. In an apparatus according to an exemplifying and non-limiting embodiment, the data processing system 102 is configured to compute the estimates τ and u_{0C} with the aid of the following formulas:

τ=(t₂−t₁)/ln(u₁/u₂), and

u_{0C}=u₁e^{(t1-t0)/τ}=u₂e^{(t2-t0)/τ}.

As u₁ and u₂ are values of the difference voltage u corresponding to the time instants t₁ and t₂ where the current I is zero, we get u₁=u_{0C}e^{-(t1-t0)/τ} and u₂=u_{0C}e^{-(t2-t0)/τ}. This yields u₁/u₂=e^{(t2-t1)/τ} and thus τ=(t₂−t₁)/ln(u₁/u₂). The value u₂ is advantageously u₁/e, in which case ln(u₁/u₂)=ln(e)=1 and τ is simply t₂−t₁.

In an apparatus according to another exemplifying and non-limiting embodiment, the data processing system 102 shown in FIG. 1a is configured to compute the estimates τ and u_{0C} with curve fitting, e.g. the least mean square “LMS” fitting, using u_{0C} and τ as fitting parameters so that the curve u_{0C}e^{-(t-t0)/τ} is fit to the curve of the difference voltage u on a time interval where the current I is zero, e.g. on the time interval from t₁ to t₂.

The data processing system 102 shown in FIG. 1a is configured to compute at least one of the following: i) an estimate for the membrane resistance Rₘ of the electrolyzer 103 as Rₘ=(u₀−u_{0C})/I₀, ii) an estimate for the charge-transfer resistance R_{ct} of the electrolyzer 103 as R_{ct}=u_{0C}/I₀, and iii) an estimate for the double-layer capacitance C_{dl} of the electrolyzer 103 as C_{dl}=τ I₀/u_{0C}.

Reversible degradation in the electrolytic cells of the electrolyzer 103 is related to an increase in the above-mentioned membrane resistance Rₘ. Thus, the membrane resistance Rₘ is indicative of a condition of the electrolyzer 103.

In an apparatus according to an exemplifying and non-limiting embodiment, the data processing system 102 is configured to compute the estimate of the membrane resistance Rₘ of the electrolyzer 103 at successive shutdowns of the electrolyzer 103 and to detect an increase of the computed estimate of the membrane resistance Rₘ.

In an apparatus according to an exemplifying and non-limiting embodiment, the data processing system 102 is configured to activate a procedure to recover from reversible degradation to improve the lifetime of the electrolyzer 103 in response to a detected increase in the computed estimate of the membrane resistance Rₘ. The procedure may comprise for example successive shutdowns and startups of the electrolyzer 103 in order to recover from the reversible degradation.

The data processing system 102 can be implemented with one or more processor circuits, each of which can be a programmable processor circuit provided with appropriate software, a dedicated hardware processor such as for example an application specific integrated circuit “ASIC”, or a configurable hardware processor such as for example a field programmable gate array “FPGA”. Furthermore, the data processing system 102 may comprise one or more memory devices each of which can be e.g. a random-access memory “RAM” circuit.

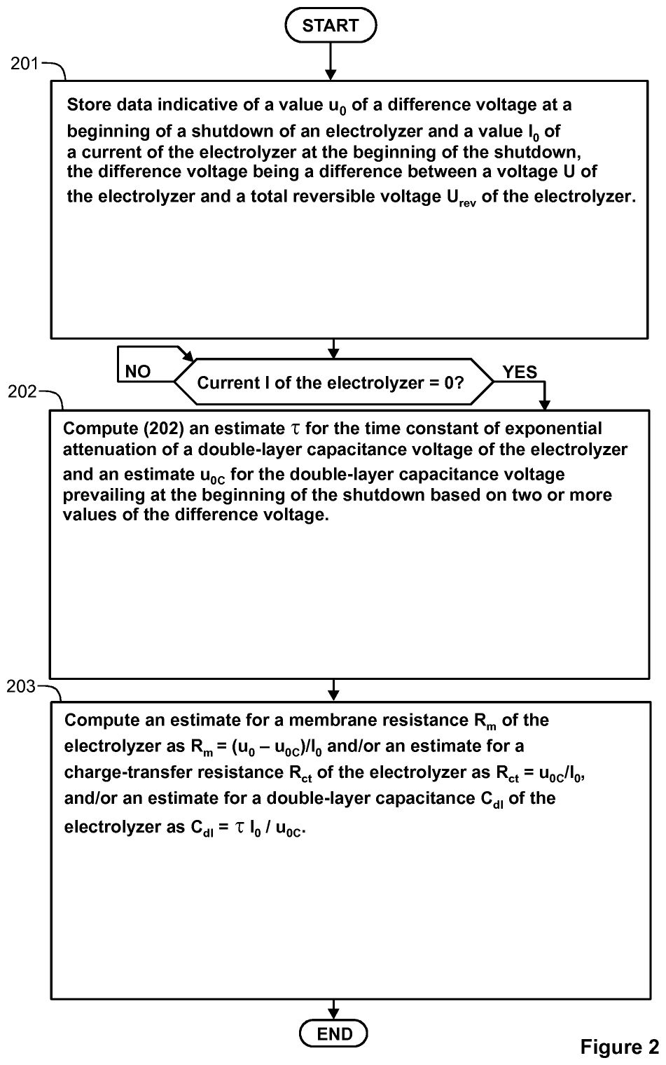

FIG. 2 shows a flowchart of a method according to an exemplifying and non-limiting embodiment for estimating electrical properties of an electrolyzer. The method comprises the following actions:
action 201: storing data indicative of a value u₀ of a difference voltage prevailing at a beginning of a shutdown of the electrolyzer and a value I₀ of a current of the electrolyzer prevailing at the beginning of the shutdown, the difference voltage being a difference between a voltage U applied on the electrolyzer and a total reversible voltage Uᵣₑᵥ of the electrolyzer,
action 202: in response to a situation in which the current I has reached zero, computing an estimate τ for a time constant of exponential attenuation of a double-layer capacitance voltage of the electrolyzer and an estimate u_{0C} for the double-layer capacitance voltage prevailing at the beginning of the shutdown based on two or more values of the difference voltage when the current is zero and thus the difference voltage equals the double-layer capacitance voltage, and
action 203: computing at least one of the following: i) an estimate for a membrane resistance Rₘ of the electrolyzer as Rₘ=(u₀−u_{0C})/I₀, ii) an estimate for a charge-transfer resistance R_{ct} of the electrolyzer as R_{ct}=u_{0C}/I₀, and iii) an estimate for a double-layer capacitance C_{dl} of the electrolyzer as C_{dl}=τ I₀/u_{0C}.

In conjunction with the above-described method, the above-mentioned value I₀ of the current is needed and only a detection of a zero current situation is needed after the beginning of the shutdown. This gives an advantage in industrial-scale electrolysis systems where it can be difficult to measure trends of high currents accurately enough.

A method according to an exemplifying and non-limiting embodiment comprises computing the estimate of the membrane resistance Rₘ of the electrolyzer at successive shutdowns of the electrolyzer and to detect an increase of the computed estimate.

A method according to an exemplifying and non-limiting embodiment comprises activating a procedure to recover from reversible degradation of electrolytic cells of the electrolyzer to improve the lifetime of the electrolyzer in response to a detected increase in the computed estimate of the membrane resistance Rₘ. In a method according to an exemplifying and non-limiting embodiment, the procedure comprises successive shutdowns and startups of the electrolyzer in order to recover from the reversible degradation.

A computer program according to an exemplifying and non-limiting embodiment comprises computer executable instructions for controlling a programmable processor to carry out actions related to a method according to any of the above-described exemplifying and non-limiting embodiments.

A computer program according to an exemplifying and non-limiting embodiment comprises software modules for estimating electrical properties of an electrolyzer. The software modules comprise computer executable instructions for controlling a programmable processor to:
store data indicative of a value u₀ of a difference voltage prevailing at a beginning of a shutdown of the electrolyzer and a value I₀ of a current of the electrolyzer prevailing at the beginning of the shutdown, the difference voltage being a difference between a voltage applied on the electrolyzer and a total reversible voltage of the electrolyzer,
in response to a situation in which the current has reached zero, compute an estimate τ for a time constant of exponential attenuation of a double-layer capacitance voltage of the electrolyzer and an estimate u_{0C} for the double-layer capacitance voltage prevailing at the beginning of the shutdown based on two or more values of the difference voltage when the current is zero and the thus difference voltage equals the double-layer capacitance voltage, and
compute at least one of the following: i) an estimate for a membrane resistance Rₘ of the electrolyzer as Rₘ=(u₀−u_{0C})/I₀, ii) an estimate for a charge-transfer resistance R_{ct} of the electrolyzer as R_{ct}=u_{0C}/I₀, and iii) an estimate for a double-layer capacitance C_{dl} of the electrolyzer as C_{dl}=τ I₀/u_{0C}.

The above-mentioned software modules can be e.g. subroutines or functions implemented with a suitable programming language.

A computer program product according to an exemplifying and non-limiting embodiment comprises a computer readable medium, e.g. a compact disc “CD”, encoded with a computer program according to an embodiment of invention.

A signal according to an exemplifying and non-limiting embodiment is encoded to carry information defining a computer program according to an embodiment of invention. In this exemplifying case, the computer program can be downloadable from a server that may constitute e.g. a part of a cloud service.

The specific examples provided in the description given above should not be construed as limiting the applicability and/or the interpretation of the appended claims. Lists and groups of examples provided in the description given above are not exhaustive unless otherwise explicitly stated.

1. An apparatus for estimating electrical properties of an electrolyzer, the apparatus comprising current and voltage sensors for measuring a voltage applied on the electrolyzer and a current of the electrolyzer, wherein the apparatus comprises a data processing system:
storing data indicative of a value u₀ of a difference voltage prevailing at a beginning of a shutdown of the electrolyzer and a value I₀ of the current of the electrolyzer prevailing at the beginning of the shutdown, the difference voltage being a difference between the voltage applied on the electrolyzer and a total reversible voltage of the electrolyzer,
in response to a situation in which the current has reached zero, computing an estimate τ for a time constant of exponential attenuation of a double-layer capacitance voltage of the electrolyzer and an estimate u_{0C} for the double-layer capacitance voltage prevailing at the beginning of the shutdown based on two or more values of the difference voltage when the current is zero and the difference voltage equals the double-layer capacitance voltage, and
computing at least one of the following: i) an estimate for a membrane resistance Rₘ of the electrolyzer as Rₘ=(u₀−u_{0C})/I₀, ii) an estimate for a charge-transfer resistance R_{ct} of the electrolyzer as R_{ct}=u_{0C}/I₀, and iii) an estimate for a double-layer capacitance C_{dl} of the electrolyzer as C_{dl}=τ I₀/u_{0C}.

2. An apparatus according to claim 1, wherein the data processing system is configured to compute the estimate of the membrane resistance Rₘ of the electrolyzer at successive shutdowns of the electrolyzer and to detect an increase of the computed estimate.

3. An apparatus according to claim 2, wherein the data processing system is configured to activate a procedure to recover from reversible degradation of electrolytic cells of the electrolyzer in response to the detected increase of the computed estimate of the membrane resistance.

4. An apparatus according to claim 3, wherein procedure comprises successive shutdowns and startups of the electrolyzer.

5. An electrolysis system comprising:
an electrolyzer,
a rectifier circuitry for receiving one or more alternating voltages and for supplying a direct current to electrodes of the electrolyzer,
a controller for controlling the direct current supplied to the electrodes of the electrolyzer, and
an apparatus for estimating electrical properties of the electrolyzer,
the apparatus comprising current and voltage sensors for measuring a voltage applied on the electrolyzer and the direct current of the electrolyzer, wherein the apparatus comprises a data processing system for:
storing data indicative of a value u₀ of a difference voltage prevailing at a beginning of a shutdown of the electrolyzer and a value I₀ of the direct current of the electrolyzer prevailing at the beginning of the shutdown, the difference voltage being a difference between the voltage applied on the electrolyzer and a total reversible voltage of the electrolyzer,
in response to a situation in which the direct current has reached zero, computing an estimate τ for a time constant of exponential attenuation of a double-layer capacitance voltage of the electrolyzer and an estimate u_{0C} for the double-layer capacitance voltage prevailing at the beginning of the shutdown based on two or more values of the difference voltage when the direct current is zero and the difference voltage equals the double-layer capacitance voltage, and
computing at least one of the following: i) an estimate for a membrane resistance Rₘ of the electrolyzer as Rₘ=(u₀−u_{0C})/I₀, ii) an estimate for a charge-transfer resistance R_{ct} of the electrolyzer as R_{ct}=u_{0C}/I₀, and iii) an estimate for a double-layer capacitance Ca, of the electrolyzer as C_{dl}=□I₀/u_{0C}.

6. An electrolysis system according to claim 5, wherein the rectifier circuitry comprises a forced-commutated converter bridge and supply inductors at an alternating voltage side of the forced-commutated converter bridge.

7. An electrolysis system according to claim 6, wherein the rectifier circuitry comprises at least one other forced-commutated converter bridge so that the direct current supplied to the electrodes of the electrolyzer is a sum of direct currents of the forced-commutated converter bridges of the rectifier circuitry.

8. An electrolysis system according to claim 5, wherein electrolyzer is configured to decompose water into hydrogen gas and oxygen gas.

9. A method for estimating electrical properties of an electrolyzer, the method comprising:
storing data indicative of a value u₀ of a difference voltage prevailing at a beginning of a shutdown of the electrolyzer and a value I₀ of a current of the electrolyzer prevailing at the beginning of the shutdown, the difference voltage being a difference between a voltage applied on the electrolyzer and a total reversible voltage of the electrolyzer,
in response to a situation in which the current has reached zero, computing an estimate τ for a time constant of exponential attenuation of a double-layer capacitance voltage of the electrolyzer and an estimate u_{0C} for the double-layer capacitance voltage prevailing at the beginning of the shutdown based on two or more values of the difference voltage when the current is zero and the difference voltage equals the double-layer capacitance voltage, and
computing at least one of the following: i) an estimate for a membrane resistance Rₘ of the electrolyzer as Rₘ=(u₀−u_{0C})/I₀, ii) an estimate for a charge-transfer resistance R_{ct} of the electrolyzer as R_{ct}=u_{0C}/I₀, and iii) an estimate for a double-layer capacitance C_{dl} of the electrolyzer as C_{dl}=□I₀/u_{0C}.

10. A method according to claim 9, wherein the method comprises computing the estimate of the membrane resistance Rₘ of the electrolyzer at successive shutdowns of the electrolyzer and to detect an increase of the computed estimate.

11. A method according to claim 10, wherein the method comprises activating a procedure to recover from reversible degradation of electrolytic cells of the electrolyzer in response to the detected increase of the computed estimate of the membrane resistance.

12. A method according to claim 11, wherein procedure comprises successive shutdowns and startups of the electrolyzer.

13. A non-transitory computer readable medium encoded with a computer program for estimating electrical properties of an electrolyzer, the computer program comprising computer executable instructions, which when executed by a programmable processor, cause the programmable processor to:
receive, from voltage and current sensors, data indicative of a voltage applied on the electrolyzer and a current of the electrolyzer,
store data indicative of a value u₀ of a difference voltage prevailing at a beginning of a shutdown of the electrolyzer and a value I₀ of the current of the electrolyzer prevailing at the beginning of the shutdown, the difference voltage being a difference between the voltage applied on the electrolyzer and a total reversible voltage of the electrolyzer,
in response to a situation in which the current has reached zero, compute an estimate τ for a time constant of exponential attenuation of a double-layer capacitance voltage of the electrolyzer and an estimate u_{0C} for the double-layer capacitance voltage prevailing at the beginning of the shutdown based on two or more values of the difference voltage when the current is zero and the difference voltage equals the double-layer capacitance voltage, and
compute at least one of the following: i) an estimate for a membrane resistance Rₘ of the electrolyzer as Rₘ=(u₀−u_{0C})/I₀, ii) an estimate for a charge-transfer resistance R_{ct} of the electrolyzer as R_{ct}=u_{0C}/I₀, and iii) an estimate for a double-layer capacitance C_{dl} of the electrolyzer as C_{dl}=τ I₀/u_{0C}.

14. (canceled)

15. An electrolysis system according to claim 6, wherein electrolyzer is configured to decompose water into hydrogen gas and oxygen gas.

16. An electrolysis system according to claim 7, wherein electrolyzer is configured to decompose water into hydrogen gas and oxygen gas.
